(19) United States
(12) Patent Application Publication
(10) Pub. No.: US 2024/0363698 A1
(43) Pub. Date: Oct. 31, 2024

(54) SIC SHIELDED GATE TRENCH MOSFET WITH IMPROVED PERFORMANCE

(71) Applicant: Nami MOS CO., LTD., New Taipei City (TW)

(72) Inventors: FU-YUAN HSIEH, New Taipei City (TW); LIN XU, SHANGHAI (CN)

(73) Assignee: Nami MOS CO., LTD., New Taipei City (TW)

(21) Appl. No.: 18/139,017

(22) Filed: Apr. 25, 2023

(51) Int. Cl. H01L 29/40; H01L 29/06; H01L 29/10; H01L 29/16; H01L 29/417; H01L 29/78

(52) U.S. Cl. CPC H01L 29/407; H01L 29/0634; H01L 29/1095; H01L 29/1608; H01L 29/41741; H01L 29/7813

(57) ABSTRACT

A SiC shielded gate trench device having a first type gate trench and a second type gate trench is disclosed. The first type gate trench is above the second type gate trench and has a trench width wider than a trench width of the second type gate trench, wherein the first type gate trench is filled with a gate electrode and a shielded gate electrode, and a grounded P-shield region surrounding the second type gate trench is under the shielded gate electrode for gate oxide electric-field reduction. The device further comprises a current spreading region surrounding the gate electrode for on-resistance reduction.

### FIELD OF THE INVENTION

This invention relates generally to semiconductor devices, and more particularly, to a silicon carbide (SiC) shielded gate trench (SGT) Metal Oxide Semiconductor Field Effect Transistor (MOSFET) having a first and a second type gate trenches for formation of a gate electrode and a shielded gate electrode in the first type gate trench, and a grounded P-shield (PS) region surrounding the second type gate trench for gate oxide electric-field reduction. The device further comprises a current spreading region surrounding the gate electrode below body regions, to achieve a lower electric-field strength of the gate oxide, lower on-resistance, smaller gate-drain charge (Qgd) and lower switching loss.

### BACKGROUND OF THE INVENTION

Because of the physical properties of SiC, SiC-MOSFETs can achieve a higher breakdown voltage, lower on-resistance and higher switching speed than Si-MOSFETs. However, SiC-MOSFETs have a higher electric-field strength at the gate oxide than Si-MOSFETs because of the poor interface state between SiC and the gate oxide requiring higher Vgs to fully turn on a device channel. E.g., for Si device, Vgs=10V can fully turn on the Si device channel but for SiC requires Vgs=18V. The higher Vgs causes higher electric filed strength at the gate oxide resulting in reliability issue.

Another issue is that a gate oxide grown at trench bottom of the SiC device is much thinner (about 3-5 times thinner) than that at trench sidewalls as shown in FIG. 1, not only causing higher Qgd but also making much higher gate oxide electric-field strength at trench bottom. The device structure described in FIG. 1 is similar to a conventional Si trench MOSFET except for the N+ SiC substrate 101 and the SiC epitaxial layer 102, and the device has n+ source regions 111 and P body regions 110. Besides, a gate trench 103 filled up with gate electrode 105 is formed in the SiC epitaxial layer 102 having a thermally grown gate oxide 109 on trench sidewalls and another gate oxide 106 on trench bottom. The thickness of the gate oxide 106 is less than a thickness of the gate oxide 109 since an oxidation rate of trench bottom on Si plane is the lowest in crystal planes of SiC.

Therefore, there is still a need in the art of the semiconductor device design and fabrication, particularly for SiC trench MOSFET design and fabrication, to provide a novel cell structure, device configuration that would resolve these difficulties and design limitations, making a SiC trench MOSFET has lower electric-field strength of the gate oxide, achieving lower on-resistance, smaller Qgd and lower switching loss.

### SUMMARY OF THE INVENTION

The present invention discloses a SiC SGT MOSFET having a first and a second type gate trenches for formation of a gate electrode and a shielded gate electrode in the first type gate trench achieving lower Qgd and lower on-resistance, and a P-shield (PS) region of a P type conductivity surrounding the second type gate trench for gate oxide electric-field reduction, wherein the shielded gate electrode is disposed in the lower portion of the first type gate trench below the gate electrode having a thick oxide layer on trench bottom and lower portion sidewalls of the first type gate trench, and the PS region is formed surrounding the second type gate trench filled up with the thick oxide layer, connecting with a body region through at least one grounded P (GP) region of aP type conductivity and shorted with a source metal. A width of the PS region can be designed narrower than that of the first type gate trench as a result of the second type gate trench is narrower than the first type gate trench. Therefore, on resistance is reduced as a result of less pinch-off effect between the two adjacent PS regions. The device further comprises a current spreading (Ncs) region surrounding the gate electrode below a body region to further avoid the pinching off effect between the two adjacent PS regions for on-resistance reduction, wherein the doping concentration of the Ncs region is higher than that of the epitaxial layer (Nepi). Because of a thicker bottom oxide layer of the device under the gate electrode, it should be capable of achieving a smaller Qgd as well as further reductions in switching loss compared to a conventional SiC MOSFET.

According to one aspect, the invention features a SiC SGT device comprising a plurality of unit cells with each unit cell in an active area comprising: an epitaxial layer of a first conductivity type on a substrate; at least one stripe gate trench being surrounded by a source region of the first conductivity type encompassed in a body region of a second conductivity type; each of the stripe gate trenches having a first type gate trench and a second type gate trench, the first type gate trench above the second type gate trench with a trench width wider than a trench width of the second type gate trench, a gate electrode and a shielded gate electrode being disposed in the first type gate trench; the shielded gate electrode being insulated from the epitaxial layer by a first insulating film, the gate electrode being insulated from the epitaxial layer by a gate oxide, the shielded gate electrode and the gate electrode being insulated from each other by an (Inter-polysilicon Oxide) IPO film, and the first insulating film having a thickness greater than a thickness of the second insulating film; a PS region of the second conductivity type for gate oxide electric-field reduction surrounding the second type gate trench filled up with the first insulating film: at least one GP region of the second conductivity type surrounding lower portion sidewalls and bottom of the first type gate trench, connecting with the body region and the PS region: the body regions and the source regions being shorted to a source metal through source contacts. Therefore, the PS region is grounded with a source metal through the grounded GP region.

According to another aspect, in some preferred embodiments, the substrate has the first conductivity type. In some other preferred embodiments, the substrate has the first conductivity type, further comprises a second PS region of the second type conductivity for gate oxide electric-filed reduction adjoining lower surface of the body region and being apart from the stripe gate trench. In some other preferred embodiments, the device further comprises a super junction (SJ) structure comprising a P column region of the second type conductivity disposed above the substrate.

According to another aspect, in some preferred embodiments, the substrate has the first conductivity type and the epitaxial layer comprises a single epitaxial layer having a uniform doping concentration. In some other preferred embodiments, the substrate has the second conductivity type and the epitaxial layer comprises a single epitaxial layer having a uniform doping concentration.

According to another aspect, in some preferred embodiments, the substrate has the second conductivity type, further comprises a plurality of heavily doped regions of the first conductivity type in the substrate to form a plurality of alternating P+ and N+ regions in the substrate.

According to another aspect, the present invention also features a SiC SGT device further comprising a current spreading region of the first conductivity type surrounding at least sidewalls of the gate electrode, wherein the current spreading layer has a higher doping concentration than that of the epitaxial layer.

According to another aspect, in some preferred embodiments, the epitaxial layer has multiple stepped epitaxial (MSE) layers comprising at least two stepped epitaxial layers of different doping concentrations decreasing stepwise in a direction from substrate to a top surface of the epitaxial layer, wherein each of the MSE layers has a uniform doping concentration as grown.

According to another aspect, in some preferred embodiment, the substrate has the first conductivity type, an Oxide Charge Balance (OCB) region of the first conductivity is formed in a mesa area between two adjacent stripe gate trenches below the body regions and above a bottom of the shielded gate electrode, a buffer region of the first conductivity type is formed between the substrate and the OCB region, and the epitaxial layer in the OCB region has MSE layers with different doping concentrations decreasing stepwise in a direction from a bottom of the shielded gate electrode to the body regions along sidewalls of the stripe gate trench, wherein each of the MSE layers has a uniform doping concentration as grown. The epitaxial layer in the buffer region has a doping concentration lower than the doping concentrations of said MSE layers in the OCB region, or higher than a doping concentration of a top epitaxial layer of the MSE layers in the OCB region but lower than a doping concentration of a bottom epitaxial layer of the MSE layers in the OCB region.

According to another aspect, in some preferred embodiment, the substrate has the second conductivity type, an OCB region of the first conductivity is formed in a mesa area between two adjacent stripe gate trenches below the body regions and above a bottom of the shielded gate electrode, a buffer region of the first conductivity type is formed between the substrate and the OCB region, and the epitaxial layer in the OCB region has MSE layers with different doping concentrations decreasing stepwise in a direction from a bottom of the shielded gate electrode to the body regions along sidewalls of the stripe gate trench, wherein each of the MSE layers has a uniform doping concentration as grown. The epitaxial layer in the buffer region has a doping concentration higher than the doping concentrations of said MSE layers in the OCB region.

According to another aspect, in some preferred embodiment, further comprising a second PS region of the second type conductivity for gate oxide electric-filed reduction adjoining lower surface of the body region and being apart from the stripe gate trench.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1 is a cross-sectional view of a conventional SiC semiconductor device having a trench gate vertical double diffused MOSFET.

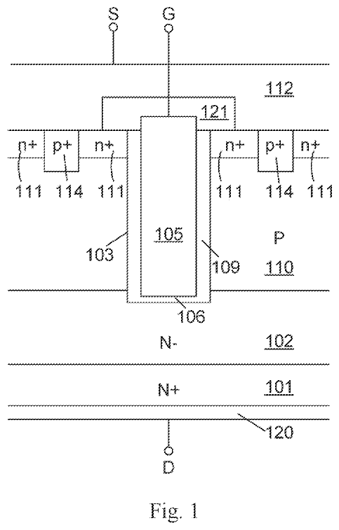

FIG. 2 is a top view of a preferred embodiment for a trench semiconductor power device with stripe cells layout according to the present invention.

FIG. 3A is a cross-sectional view showing a preferred A-A′ cross section of FIG. 2 according to the present invention.

FIG. 3B is a cross-sectional view showing a preferred B-B′ cross section of FIG. 2 according to the present invention.

FIG. 3C is a cross-sectional view showing another preferred A-A cross section of FIG. 2 according to the present invention.

FIG. 3D is a cross-sectional view showing another preferred A-A′ cross section of FIG. 2 according to the present invention

FIG. 4A is a cross-sectional view showing another preferred A-A′ cross section of FIG. 2 according to the present invention, wherein the doping concentration variations of the N type epitaxial layer as grown are depicted along the vertical direction.

FIG. 4B is a cross-sectional view showing another preferred B-B′ cross section of FIG. 2 according to the present invention, wherein the doping concentration variations of the N type epitaxial layer as grown are depicted along the vertical direction.

FIG. 4C is a cross-sectional view showing another preferred A-A′ cross section of FIG. 2 according to the present invention, wherein the doping concentration variations of the N type epitaxial layer as grown are depicted along the vertical direction.

FIG. 5A is a cross-sectional view showing another preferred A-A′ cross section of FIG. 2 according to the present invention, wherein the doping concentration variations of the N type epitaxial layer as grown are depicted along the vertical direction.

FIG. 5B is a cross-sectional view showing another preferred B-B′ cross section of FIG. 2 according to the present invention, wherein the doping concentration variations of the N type epitaxial layer as grown are depicted along the vertical direction.

FIG. 5C is a cross-sectional view showing another preferred A-A′ cross section of FIG. 2 according to the present invention, wherein the doping concentration variations of the N type epitaxial layer as grown are depicted along the vertical direction.

FIG. 6A is a cross-sectional view showing another preferred A-A′ cross section of FIG. 2 according to the present invention, wherein the doping concentration variations of the N type epitaxial layer as grown are depicted along the vertical direction.

FIG. 6B is a cross-sectional view showing another preferred A-A′ cross section of FIG. 2 according to the present invention, wherein the doping concentration variations of the N type epitaxial layer as grown are depicted along the vertical direction.

FIG. 7A is a cross-sectional view showing another preferred A-A′ cross section of FIG. 2 according to the present invention, wherein the doping concentration variations of the N type epitaxial layer as grown are depicted along the vertical direction.

FIG. 7B is a cross-sectional view showing another preferred A-A′ cross section of FIG. 2 according to the present invention, wherein the doping concentration variations of the N type epitaxial layer as grown are depicted along the vertical direction.

FIG. 8A is a cross-sectional view showing another preferred A-A′ cross section of FIG. 2 according to the present invention.

FIG. 8B is a cross-sectional view showing another preferred B-B′ cross section of FIG. 2 according to the present invention.

FIG. 8C is a cross-sectional view showing another preferred A-A′ cross section of FIG. 2 according to the present invention.

FIG. 9A is a cross-sectional view showing another preferred A-A′ cross section of FIG. 2 according to the present invention.

FIG. 9B is a cross-sectional view showing another preferred A-A′ cross section of FIG. 2 according to the present invention.

FIG. 10A is a cross-sectional view showing another preferred A-A′ cross section of FIG. 2 according to the present invention.

FIG. 10B is a cross-sectional view showing another preferred A-A′ cross section of FIG. 2 according to the present invention.

FIG. 11 is a cross-sectional view showing another preferred A-A′ cross section of FIG. 2 according to the present invention.

FIG. 12 is a cross-sectional view showing another preferred A-A′ cross section of FIG. 2 according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”. “bottom”, “front”. “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

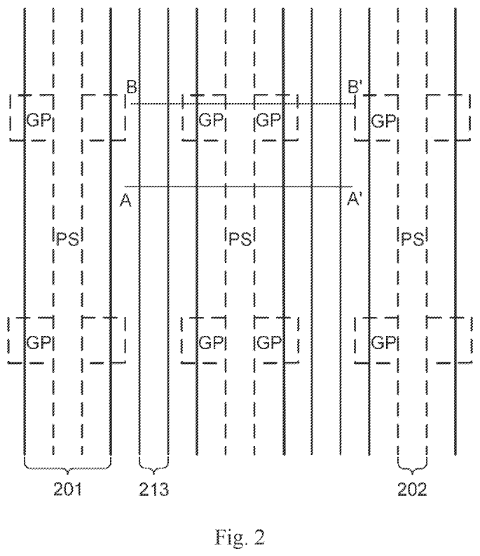

Please refer to FIG. 2 for a top view of a Si power device with stripe cells layout. A gate trench 201 surrounds a P-shield (PS) region 202 in each unit cell, wherein the gate trench 201 has a stripe shape, and the PS region 202 is connected with grounded P (GP) regions. Trenched source contacts 203 are disposed between the adjacent gate trenches 201.

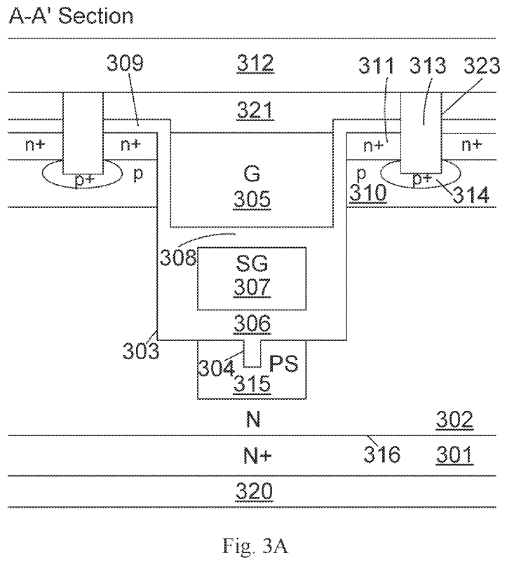

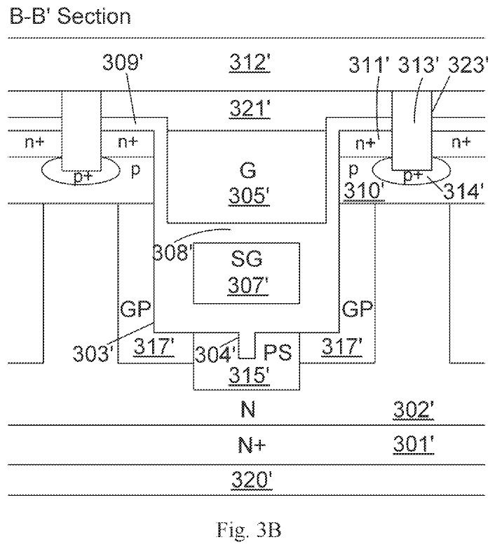

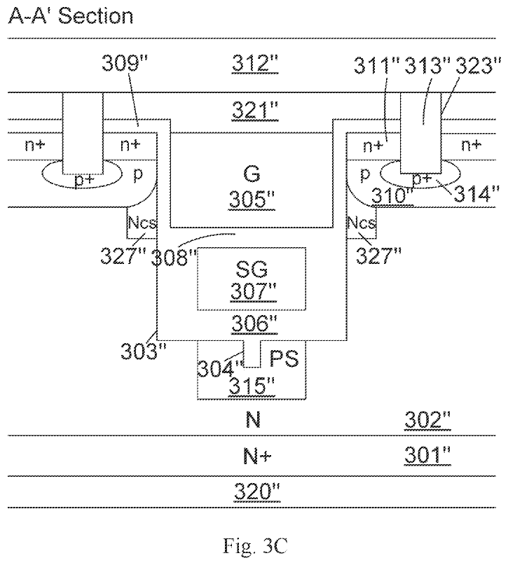

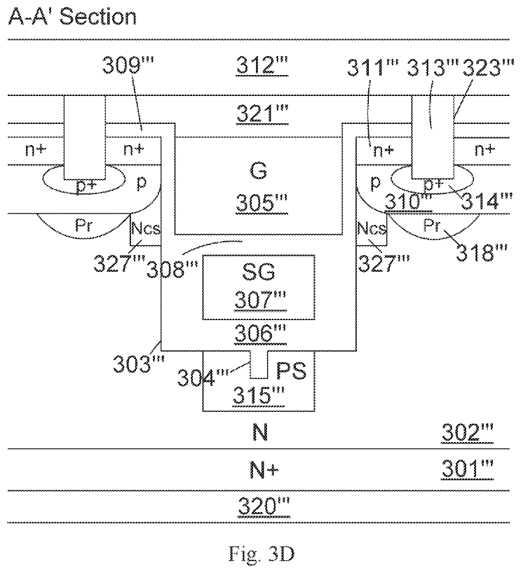

Please refer to FIG. 3A for a preferred A-A′ cross-sectional view of FIG. 2. A SiC SGT device comprising a trench MOSFET formed on an N+ type SiC substrate 301 with a less doped N type SiC epitaxial layer 302 extending thereon, wherein the N+ substrate 301 is coated with a back metal 320 of Ti/Ni/Ag on rear side as a drain metal. Inside the N epitaxial layer 302, a plurality of gate trenches having a first type gate trenches 303 and a second type gate trenches 304 are formed vertically downward from a top surface of the N epitaxial layer 302 and not reaching the common interface 316 between the N epitaxial layer 302 and the N+ substrate 301, wherein the first type gate trenches 303 are above the second type gate trenches 304 and width of the first type gate trenches 303 is greater than that of the second type gate trenches 304. Inside each of the first type gate trenches 303, a shielded gate electrode (SG, as illustrated) 307 is disposed in the lower portion and a single gate electrode (G, as illustrated) 305 is disposed in the upper portion. The shielded gate electrode 307 is insulated from the adjacent epitaxial layer by a first insulating film 306, and the gate electrode 305 is insulated from the adjacent epitaxial layer by a gate oxide 309, wherein the gate oxide 309 has a thinner thickness than a thickness of the first insulating film 306 which has a uniform thickness along trench sidewalls, meanwhile, the shielded gate electrode 307 and the gate electrode 305 is insulated from each other by a second insulating film 308 as an IPO layer. Besides, the second type gate trenches 304 are filled up with the first insulating film 306. Between every two adjacent first type gate trenches 303, a p body region 310 with n+ source regions 311 thereon are extending near a top surface of the N epitaxial layer 302. An interlayer dielectric film 321 is stacked on the epitaxial layer 302, and a source metal 312 is formed onto the interlayer dielectric film 321. The p body regions 310 and the n+ source regions 311 are further shorted to the source metal 312 through a plurality of trenched contacts 323 filled with contact metal plugs and metal barriers 313 and surrounded by p+ heavily doped regions 314 around bottoms underneath the n+ source regions 311. According to the invention, the PS regions 315, which are adjacent to sidewalls and bottoms of the second type gate trenches 304, are introduced into the N epitaxial layer 302 by an angle ion-implantation or combination of a zero-degree ion implantation of boron through sidewalls and bottom of the second type gate trenches 304, or by a BSG layer deposition procedure. Width of the PS regions 315 is designed narrower than that of the first type gate trench 303 as the second type gate trench 304 has a narrower width than the first type gate trench 303.

Please refer to FIG. 3B for a preferred B-B′ cross-sectional view of FIG. 2, the SiC SGT device has a similar structure to FIG. 3A, except that in the present invention. GP regions 317′ are formed surrounding sidewalls and bottom of the first type gate trench 303′, connecting with the p body regions 310′ and the P-shield (PS) region 315′ and being shorted to the source metal 312′. Width of the PS region 315′ can be designed narrower than that of the first type gate trench 303′ as the second type gate trench 304′ has a narrower width than the first type gate trench 303′. Therefore, on resistance is reduced as a result of less pinch-off effect between the two adjacent PS regions 315′.

Please refer to FIG. 3C for another preferred A-A′ cross-sectional view of FIG. 2. The SiC SGT device has a similar structure to FIG. 3A, except that in the present structure, a current spreading layer 327″ of the first conductivity type (Ncs, as illustrated) is encompassed in upper portion of the epitaxial layer 302″ and below the p body regions 310″ and surrounds at least sidewalls of the gate electrode 305″. The Ncs region 327″ is introduced to avoid the formation of pinching off current path between the two PS regions 315″, wherein the Ncs region 327″ has a higher doping concentration than that of the N epitaxial layer 302″ for on-resistance reduction.

Please refer to FIG. 3D for another preferred A-A′ cross-sectional view of FIG. 2. The SiC SGT device has a similar structure to FIG. 3C, except that the present structure further comprises p type gate oxide electric field reducing regions 318′″ (Pr, as illustrated) as second PS regions, adjoining lower surfaces of the p body regions 310′″ and being apart from the gate trenches.

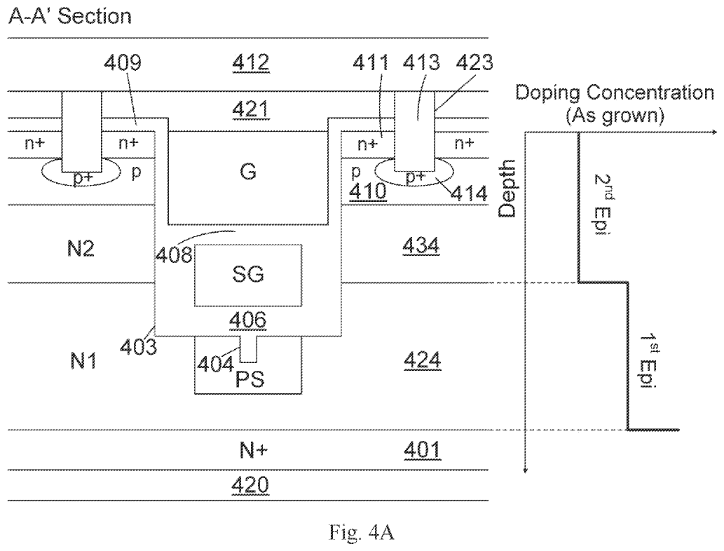

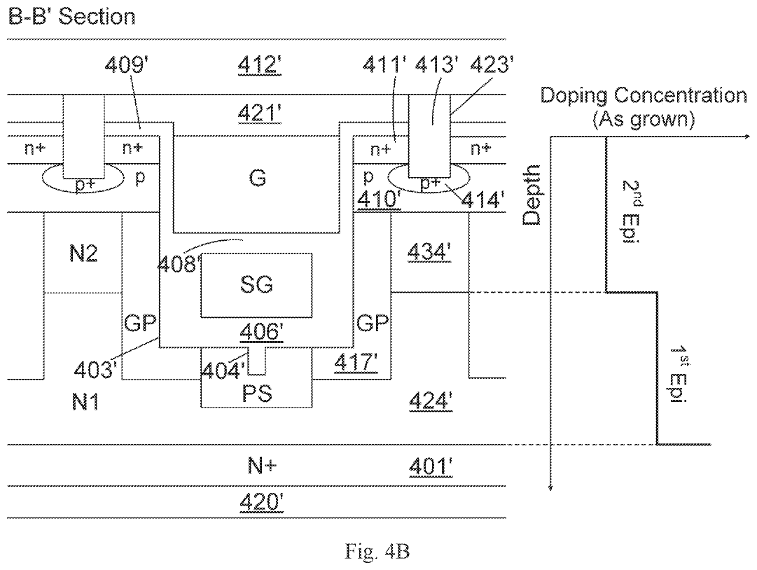

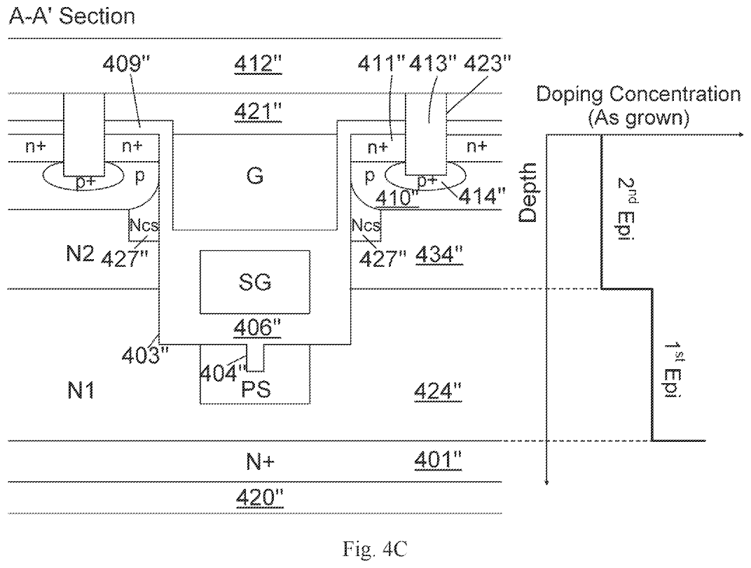

Please refer to FIG. 4A for another preferred A-A′ cross-sectional view of FIG. 2, wherein the doping concentration variations of the N type epitaxial layer as grown are depicted along the vertical direction. The SiC SGT device has a similar structure to FIG. 3A, except for the different epitaxial layers. In this invention, the N type epitaxial layer comprises two stepped epitaxial layers of different doping concentrations including a bottom 1^{st} epitaxial layer (N1, as illustrated) 424 with a doping concentration D1 and a top 2^{nd} epitaxial layer (N2, as illustrated) 434 above the bottom 1^{st} epitaxial layer 424 with a doping concentration D2, wherein D2<D1, to increase the breakdown voltage and lower the specific on-resistance.

Please refer to FIG. 4B for another preferred B-B′ cross-sectional view of FIG. 2, wherein the doping concentration variations of the N type epitaxial layer as grown are depicted along the vertical direction. The SiC SGT device has a similar structure to FIG. 3B, except for the different epitaxial layers. In this invention, the N type epitaxial layer comprises two stepped epitaxial layers of different doping concentrations including a bottom 1^{st} epitaxial layer (N1, as illustrated) 424′ with a doping concentration D1 and a top 2^{nd} epitaxial layer (N2, as illustrated) 434′ above the bottom 1^{st} epitaxial layer 424′ with a doping concentration D2, wherein D2<D1, to increase the breakdown voltage and lower the specific on-resistance.

Please refer to FIG. 4C for another preferred A-A′ cross-sectional view of FIG. 2, wherein the doping concentration variations of the N type epitaxial layer as grown are depicted along the vertical direction. The SiC SGT device has a similar structure to FIG. 3C, except for the different epitaxial layers. In this invention, the N type epitaxial layer comprises two stepped epitaxial layers of different doping concentrations including a bottom 1^{st} epitaxial layer (N1, as illustrated) 424″ with a doping concentration D1 and a top 2^{nd} epitaxial layer (N2, as illustrated) 434″ above the bottom 1^{st} epitaxial layer 424″ with a doping concentration D2, wherein D2<D1, to increase the breakdown voltage and lower the specific on-resistance.

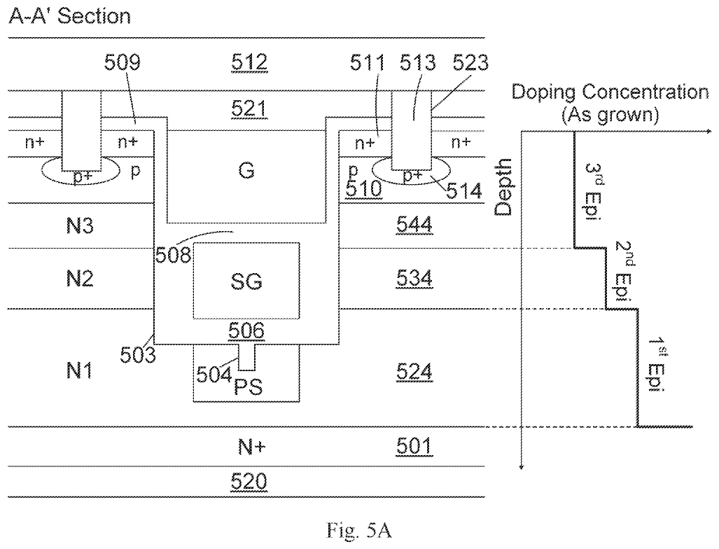

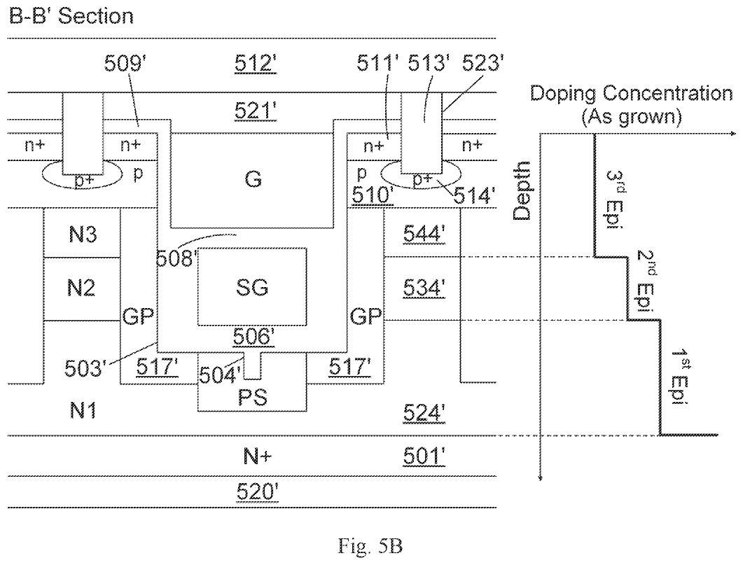

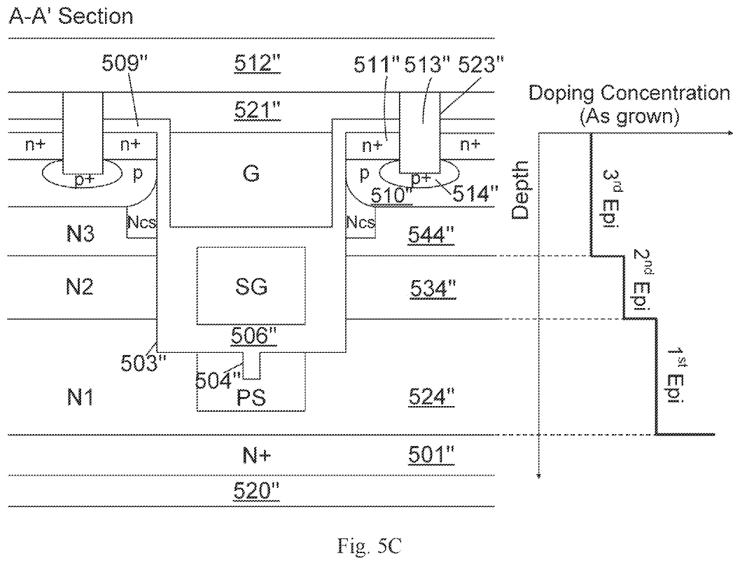

Please refer to FIG. 5A for another preferred A-A′ cross-sectional view of FIG. 2, wherein the doping concentration variations of the N type epitaxial layer as grown are depicted along the vertical direction. The SiC SGT device has a similar structure to FIG. 4A, except for the different epitaxial layers. In this invention, the N type epitaxial layer comprises three stepped epitaxial layers of different doping concentrations including a bottom 1^{st} epitaxial layer (N1, as illustrated) 524 with a doping concentration D1, a middle 2^{nd} epitaxial layer (N2, as illustrated) 534 above the 1^{st} epitaxial layer 524 with a doping concentration D2 and a top 3^{rd} epitaxial layer (N3, as illustrated) 544 above the 2^{nd} epitaxial layer 534 with a doping concentration D3, wherein D3<D2<D1. The D2 can be an average of D1 and D3.

Please refer to FIG. 5B for another preferred B-B′ cross-sectional view of FIG. 2, wherein the doping concentration variations of the N type epitaxial layer as grown are depicted along the vertical direction. The SiC SGT device has a similar structure to FIG. 4B, except for the different epitaxial layers. In this invention, the N type epitaxial layer comprises three stepped epitaxial layers of different doping concentrations including a bottom 1^{st} epitaxial layer (N1, as illustrated) 524′ with a doping concentration D1, a middle 2^{nd} epitaxial layer (N2, as illustrated) 534′ above the 1^{st} epitaxial layer 524′ with a doping concentration D2 and a top 3^{rd} epitaxial layer (N3, as illustrated) 544′ above the 2^{nd} epitaxial layer 534′ with a doping concentration D3, wherein D3<D2<D1. The D2 can be an average of D1 and D3.

Please refer to FIG. 5C for another preferred A-A′ cross-sectional view of FIG. 2, wherein the doping concentration variations of the N type epitaxial layer as grown are depicted along the vertical direction. The SiC SGT device has a similar structure to FIG. 4C, except for the different epitaxial layers. In this invention, the N type epitaxial layer comprises three stepped epitaxial layers of different doping concentrations including a bottom 1^{st} epitaxial layer (N1, as illustrated) 524″ with a doping concentration D1, a middle 2^{nd} epitaxial layer (N2, as illustrated) 534″ above the 1^{st} epitaxial layer 524″ with a doping concentration D2 and a top 3^{rd} epitaxial layer (N3, as illustrated) 544″ above the 2^{nd} epitaxial layer 534″ with a doping concentration D3, wherein D3<D2<D1. The D2 can be an average of D1 and D3.

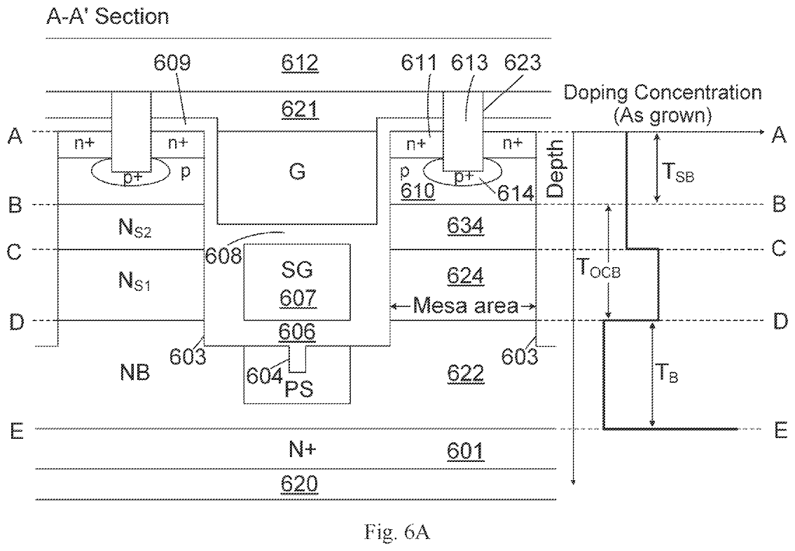

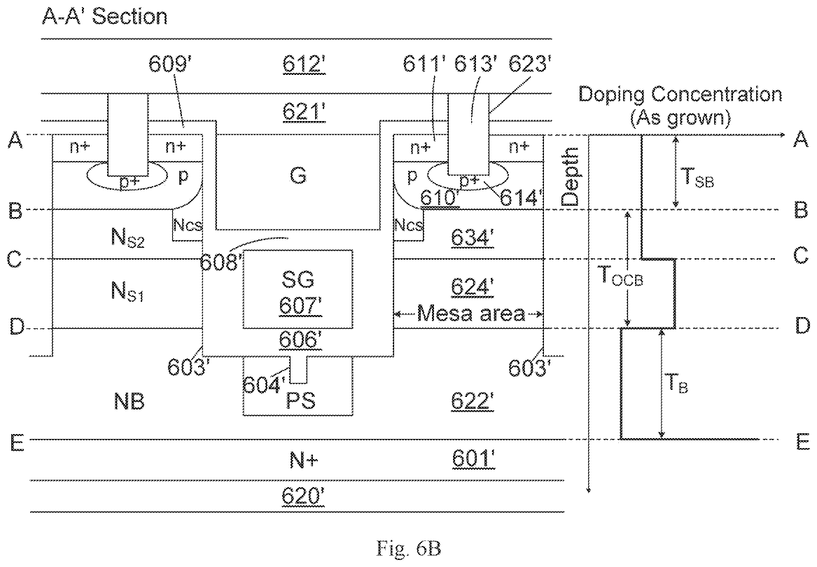

Please refer to FIG. 6A for another preferred A-A′ cross-sectional view of FIG. 2, wherein the doping concentration variations of the N type epitaxial layer as grown are depicted along the vertical direction. The SiC SGT device has a similar structure to FIG. 5A, except the epitaxial layer. In FIG. 6A, the epitaxial layer comprises a source-body (SB) region T_{SB} (between A-A and B-B lines) on top portion of the epitaxial layer, an oxide charge balance (OCB) region T_{OCB} (between B-B and D-D lines) formed in a mesa area between the two adjacent first type gate trenches 603 below the body regions 610 and above a bottom of the shielded gate electrode 607 and a buffer region T_{B} formed between the N+ substrate 601 and a bottom of the shielded gate electrode 607 (between D-D and E-E lines), the epitaxial layer in the OCB region has two stepped epitaxial layers with different doping concentrations including a bottom 1^{st} epitaxial layer (N_{S1}, as illustrated between C-C and D-D lines) 624 above the buffer epitaxial layer (N_{B}, as illustrated between D-D and E-E lines) 622 with a doping concentration D1, and a top 2^{nd} epitaxial layer (N_{S2}, as illustrated between B-B and C-C lines) 634 above the 1^{st} epitaxial layer 624 with a doping concentration D2, wherein D2<D1. Moreover, the epitaxial layer in the source regions and body regions T_{SB} has a doping concentration same as that of the top 2^{nd} epitaxial layer 634 of the MSE layers in the OCB region T_{OCB}, and the buffer epitaxial layer 622 has a doping concentration DB lower than doping concentrations of the MSE layers in the OCB region T_{OCB}.

Please refer to FIG. 6B for another preferred A-A′ cross-sectional view of FIG. 2, wherein the doping concentration variations of the N type epitaxial layer as grown are depicted along the vertical direction. The SiC SGT device has a similar structure to FIG. 5C, except for the different epitaxial layers. In FIG. 6B, an OCB region T_{OCB} (between B-B and D-D lines) is formed in a mesa area between the two adjacent first type gate trenches 603′ below the body regions 610′ and above a bottom of the shielded gate electrode 607′, a buffer region T_{B} is formed between the N+ substrate and a bottom of the shielded gate electrode 607′ (between D-D and E-E lines), the epitaxial layer in the OCB region has two stepped epitaxial layers with different doping concentrations including a bottom 1^{st} epitaxial layer (N_{S1}, as illustrated between C-C and D-D lines) 624′ above the buffer epitaxial layer (N_{B}, as illustrated between D-D and E-E lines) 622′ with a doping concentration D1, and a top 2^{nd} epitaxial layer (N_{S2}, as illustrated between B-B and C-C lines) 634′ above the 1^{st} epitaxial layer 624′ with a doping concentration D2, wherein D2<D1. Moreover, the epitaxial layer in the source regions and body regions T_{SB} has a doping concentration same as that of the top 2^{nd} epitaxial layer 634′ of the MSE layers in the OCB region T_{OCB}, and the buffer epitaxial layer 622′ has a doping concentration DB lower than that of each of the MSE layers in the OCB region T_{OCB}.

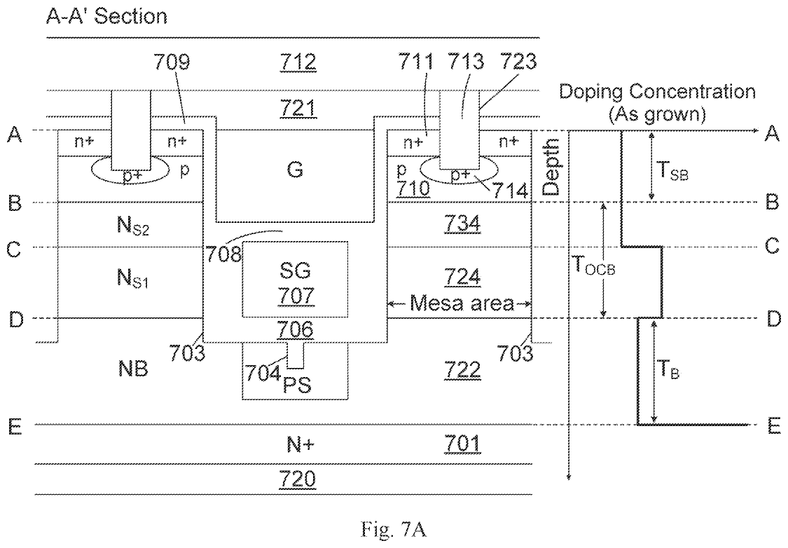

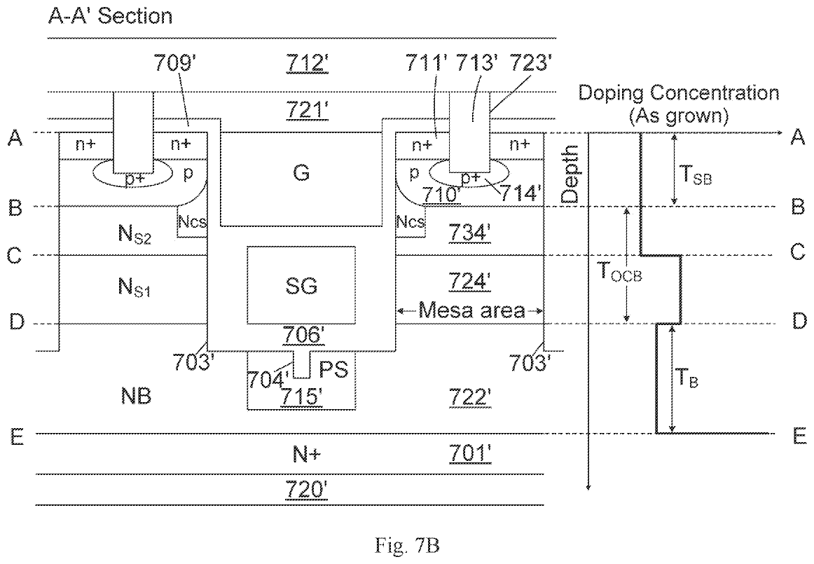

Please refer to FIG. 7A for another preferred A-A′ cross-sectional view of FIG. 2, wherein the doping concentration variations of the N type epitaxial layer as grown are depicted along the vertical direction. The SiC SGT device has a similar structure to FIG. 6A, except for the different doping concentration of the buffer region T_{B}. In FIG. 7A, the epitaxial layer in the buffer region (NB, as illustrated between D-D and E-E lines) 722 has a doping concentration DB lower than a doping concentration D1 of a bottom 1^{st} epitaxial layer (N_{S1}, as illustrated between C-C and D-D lines) 724 in the OCB region T_{OCB} but higher than a doping concentration D2 of a top 2^{nd} epitaxial layer (N_{S2}, as illustrated between B-B and C-C lines) 734 in the OCB region T_{OCB}.

Please refer to FIG. 7B for another preferred A-A′ cross-sectional view of FIG. 2, wherein the doping concentration variations of the N type epitaxial layer as grown are depicted along the vertical direction. The SiC SGT device has a similar structure to FIG. 6B, except for the different doping concentration of the buffer region T_{B}. In FIG. 7B, the epitaxial layer in the buffer region (NB, as illustrated between D-D and E-E lines) 722′ has a doping concentration DB lower than a doping concentration D1 of a bottom 1^{st} epitaxial layer (N_{S1}, as illustrated between C-C and D-D lines) 724′ in the OCB region T_{OCB} but higher than a doping concentration D2 of a top 2^{nd} epitaxial layer (N_{S2}, as illustrated between B-B and C-C lines) 734′ in the OCB region T_{OCB}.

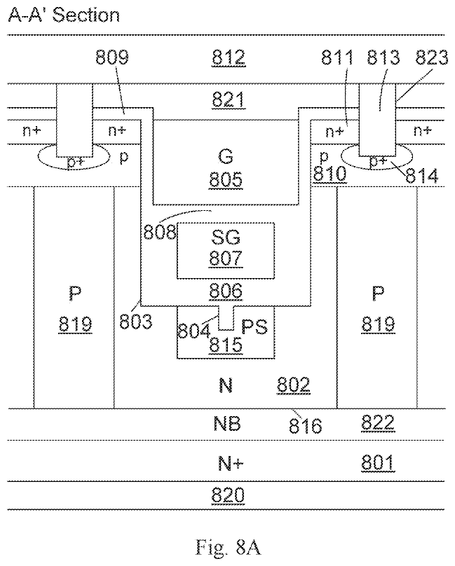

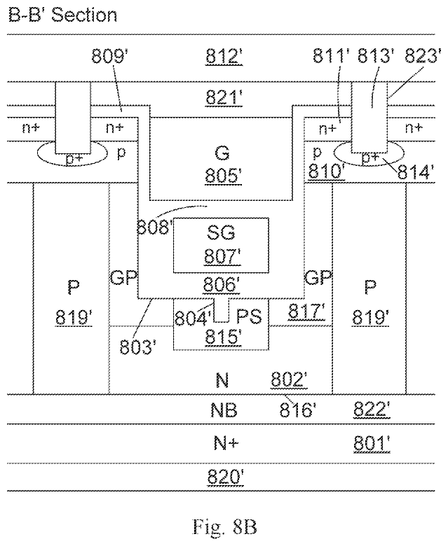

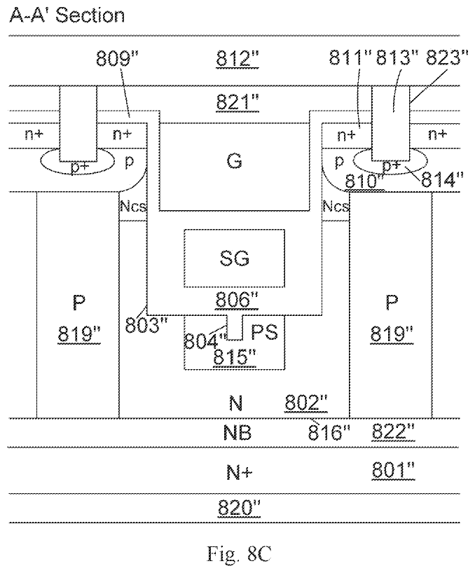

Please refer to FIG. 8A for another preferred A-A′ cross-sectional view of FIG. 2. The SiC SGT device has a similar structure to FIG. 3A, except that in FIG. 8A, the invention further comprises a N buffer layer (NB, as illustrated) 822 with a resistivity Rn sandwiched between the N+ substrate 801 and the N epitaxial layer 802, the N epitaxial layer 802 comprises a single epitaxial layer having a uniform doping concentration with a resistivity R, wherein the R<the Rn. Besides, P column regions 819 are introduced into the N epitaxial layer 802 to form a SJ region, comprising a plurality of alternating P column regions 819 and N regions 802. The P column regions 819 are formed below the p body regions 810 and touch to the bottom surface 816 of the N epitaxial layer 802 by multiple epi method or by opening a deep trench filled up with an epitaxial layer of the second conductivity type method.

Please refer to FIG. 8B for another preferred B-B′ cross-sectional view of FIG. 2. The SiC SGT device has a similar structure to FIG. 3B, except that in FIG. 8B, the invention further comprises a N buffer layer (NB, as illustrated) 822′ with a resistivity Rn sandwiched between the N+ substrate 801′ and the N epitaxial layer 802′, the N epitaxial layer 802′ comprises a single epitaxial layer having a uniform doping concentration with a resistivity R, wherein the R<the Rn. Besides, P column regions 819′ are introduced into the N epitaxial layer 802′ to form a SJ region, comprising a plurality of alternating P regions 819′ and N regions 802′. The P column regions 819′ are formed below the p body regions 810′ and touch to the bottom surface 816′ of the N epitaxial layer 802′ by multiple epi method or by opening a deep trench filled up with an epitaxial layer of the second conductivity type method.

Please refer to FIG. 8C for another preferred A-A′ cross-sectional view of FIG. 2. The SiC SGT device has a similar structure to FIG. 3C, except that in FIG. 8C, the invention further comprises a N buffer layer (NB, as illustrated) 822″ with a resistivity Rn sandwiched between the N+ substrate 801″ and the N epitaxial layer 802″, the N epitaxial layer 802″ comprises a single epitaxial layer having a uniform doping concentration with a resistivity R, wherein the R<the Rn. Besides, P column regions 819″ are introduced into the N epitaxial layer 802″ to form a SJ region, comprising a plurality of alternating P regions 819″ and N regions 802″. The P column regions 819″ are formed below the p body regions 810″ and touch to the bottom surface 816″ of the N epitaxial layer 802″ by multiple epi method or by opening a deep trench filled up with an epitaxial layer of the second conductivity type method.

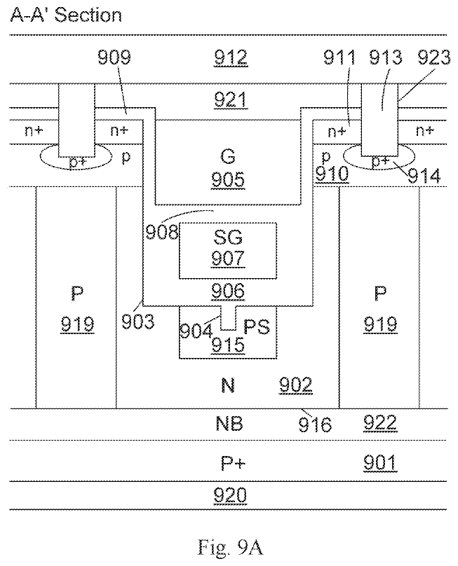

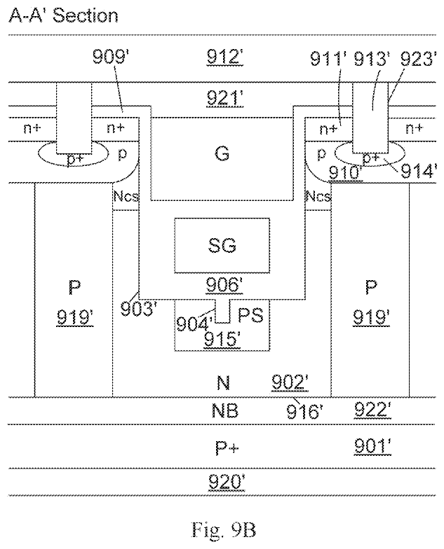

Please refer to FIG. 9A for another preferred A-A′ cross-sectional view of FIG. 2. The N-channel SiC SGT device representing an Insulating Gate Bipolar Transistor (IGBT) device has a similar structure to FIG. 8A, except for the different substrate and the R>the Rn. In this invention, the IGBT is formed onto a P+ substrate 901.

Please refer to FIG. 9B for another preferred A-A′ cross-sectional view of FIG. 2. The N-channel SiC SGT device representing an IGBT device has a similar structure to FIG. 8C, except for the different substrate. In this invention, the IGBT is formed onto a P+ substrate 901′.

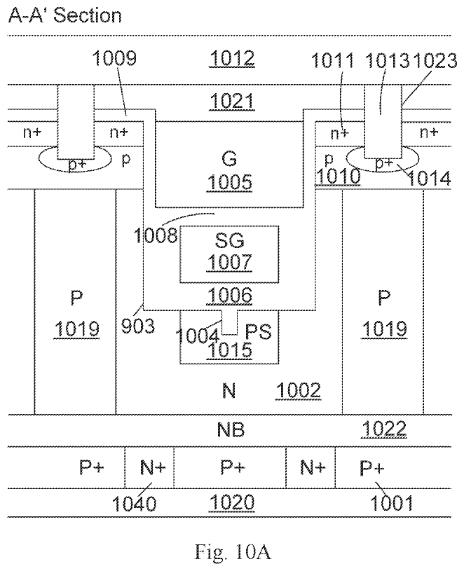

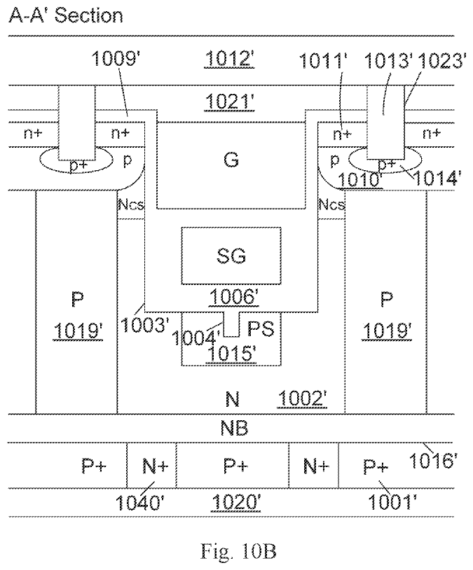

Please refer to FIG. 10A for another preferred A-A′ cross-sectional view of FIG. 2. The N-channel SiC SGT dev ice has a similar structure to FIG. 9A, except that, the IGBT in FIG. 10A further comprises a plurality of heavily doped N+ regions 1040 formed in the P+ substrate 1001 to form a plurality of alternating P+ and N+ regions in the substrate.

Please refer to FIG. 10B for another preferred A-A′ cross-sectional view of FIG. 2. The N-channel SiC SGT device has a similar structure to FIG. 9B, except that, the IGBT in FIG. 10B further comprises a plurality of heavily doped N+ regions 1040′ formed in the P+ substrate 1001′ to form a plurality of alternating P+ and N+ regions in the substrate.

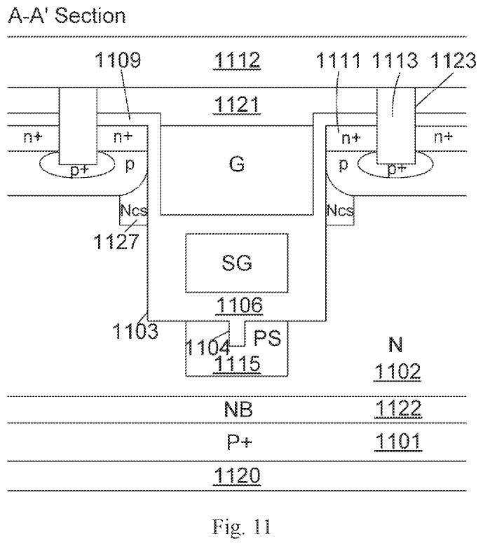

Please refer to FIG. 11 for another preferred A-A′ cross-sectional view of FIG. 2. The N-channel SiC SGT device representing an IGBT device has a similar structure to FIG. 3C, except for a substrate with a different conductivity type and an additional buffer layer 1122. In this invention, the IGBT is formed on a P+ substrate 1101.

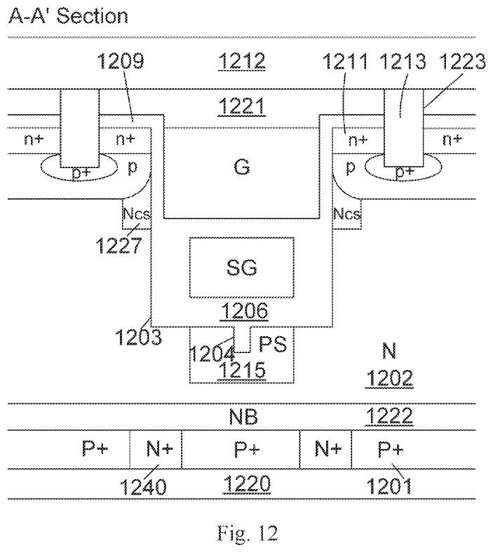

Please refer to FIG. 12 for another preferred A-A′ cross-sectional view of FIG. 2. The N-channel SiC SGT device has a similar structure to FIG. 11, except that, the IGBT in FIG. 12 further comprises an additional buffer layer 1222 and a plurality of heavily doped N+ regions 1240 formed in the P+ substrate 1201 to form a plurality of alternating P+ and N+ regions in the substrate.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A SiC shielded gate trench (SGT) device comprising a plurality of unit cells with each unit cell in an active area comprising:
an epitaxial layer of a first conductivity type on a substrate;
at least one stripe gate trench surrounded by a source region of said first conductivity type encompassed in a body region of a second conductivity type;
said stripe gate trench having a first type gate trench and a second type gate trench; said first type gate trench is above said second type gate trench and has a trench width wider than a trench width of said second type gate trench;
said first type gate trench being filled with a gate electrode and a shielded gate electrode; said shielded gate electrode being insulated from said epitaxial layer by a first insulating film, said gate electrode being insulated from said epitaxial layer by a gate oxide, said shielded gate electrode and said gate electrode being insulated from each other by an (Inter-polysilicon Oxide) IPO film, said gate oxide surrounding said gate electrode and having a less thickness than a thickness of said first insulating film;
a P-shield region of said second conductivity type for gate oxide electric-field reduction surrounding said second type gate trench filled up with said first insulating film;
at least one grounded P region of said second conductivity type surrounding sidewalls and a bottom of said first type gate trench, connecting with said body regions and said P-shield region; and
said body region and said source region being shorted to a source metal through source contacts.

2. The SiC SGT device of claim 1, wherein said gate electrode is disposed above said shielded gate electrode.

3. The SiC SGT device of claim 1, wherein said epitaxial layer is a single epitaxial layer with an uniform doping concentration.

4. The SiC SGT device of claim 1, wherein said epitaxial layer has multiple stepped epitaxial (MSE) layers with different doping concentrations decreasing stepwise in a direction from said substrate to a top surface of said epitaxial layer, wherein each of said MSE layers has an uniform doping concentration as grown.

5. The SiC SGT device of claim 4, wherein said epitaxial layer comprises at least two stepped epitaxial layers of different doping concentrations including a bottom epitaxial layer with a doping concentration D1 and a top epitaxial layer above said bottom epitaxial layer with a doping concentration D2, wherein said D2<said D1.

6. The SiC SGT device of claim 4, wherein said epitaxial layer comprises at least three stepped epitaxial layers of different doping concentration including a bottom epitaxial layer with a doping concentration D1, a middle epitaxial layer with a doping concentration D2 and a top epitaxial layer with a doping concentration D3, wherein said D3<said D2<said D1.

7. The SiC SGT device of claim 1, further comprising a current spreading region of said first conductivity type surrounding at least sidewalls of said gate electrode below said body region, wherein said current spreading region has a higher doping concentration than a doping concentration of said epitaxial layer.

8. The SiC SGT device of claim 1, wherein said substrate has said first conductivity type.

9. The SiC SGT device of claim 1, further comprising a second P-shield region of said second type conductivity for gate oxide electric-filed reduction adjoining lower surface of said body region and being apart from said stripe gate trench.

10. The SiC SGT device of claim 1, wherein said substrate has said second conductivity type.

11. The SiC SGT device of claim 1, wherein said substrate has said second conductivity type, further comprising a plurality of heavily doped regions of said first conductivity type in said substrate to form a plurality of alternating P+ and N+ regions in said substrate.

12. The SiC SGT device of claim 1, wherein said substrate has first conductivity type, further comprising a super junction structure comprising a P column region of said second type conductivity disposed on a buffer layer of said first conductivity type with a resistivity Rn sandwiched between said substrate and said epitaxial layer, and said P column region connected to said body region.

13. The SiC SGT device of claim 12, wherein said substrate has said first conductivity type and said epitaxial layer comprises a single epitaxial layer having an uniform doping concentration.

14. The SiC SGT device of claim 12, wherein said substrate has said first conductivity type and said epitaxial layer comprises a single epitaxial layer having an uniform doping concentration with a resistivity R, said R<said Rn.

15. The SiC SGT device of claim 12, wherein said substrate has said second conductivity type and said epitaxial layer comprises a single epitaxial layer having an uniform doping concentration with a resistivity R, said R>said Rn.

16. The SiC SGT device of claim 12, wherein said substrate has said second conductivity type, further comprising a plurality of heavily doped regions of said first conductivity type in said substrate to form a plurality of alternating P+ and N+ regions in said substrate.

17. The SiC SGT device comprising a plurality of unit cells with each unit cell in an active area comprising:
an epitaxial layer of a first conductivity type on a substrate of said first conductivity type;
at least one stripe gate trench surrounded by a source region of said first conductivity type encompassed in a body region of a second conductivity type;
said stripe gate trench having a first type gate trench and a second type gate trench; said first type gate trench is above said second type gate trench and has a trench width wider than a trench width of said second type gate trench;
said first type gate trench being filled with a gate electrode and a shielded gate electrode: said shielded gate electrode being insulated from said epitaxial layer by a first insulating film, said gate electrode being insulated from said epitaxial layer by a gate oxide, said shielded gate electrode and said gate electrode being insulated from each other by an (inter-polysilicon oxide) IPO film, said gate oxide surrounding said gate electrode and having a less thickness than a thickness of said first insulating film;
a P-shield region of said second conductivity type for gate oxide electric-field reduction surrounding said second type gate trench filled up with said first insulating film;
at least one grounded P region of said second conductivity type surrounding sidewalls and a bottom of said first type gate trench, connecting with said body region and said P-shield gate region;
said epitaxial layer further comprises a source-body (SB) region, an oxide charge balance (OCB) region and a buffer region;
said SB region formed on top portion of said epitaxial layer;
said OCB region of said first conductivity type formed in a mesa area between two adjacent said first type gate trenches below said body region and above a bottom of said shielded gate electrode;
said buffer region of said first conductivity in said epitaxial layer formed between said substrate and said OCB region; and
said epitaxial layer in said OCB region has multiple stepped epitaxial (MSE) layers with different doping concentrations decreasing stepwise in a direction from a bottom of said shielded gate electrode to said body region along sidewalls of said stripe gate trench, wherein each of said MSE layers has an uniform doping concentration as grown.

18. The SiC SGT device of claim 17, wherein said epitaxial layer in said buffer region has a doping concentration lower than doping concentrations of said MSE layers in said OCB region.

19. The SiC SGT device of claim 17, wherein said epitaxial layer in said OCB region comprises at least two stepped epitaxial layers of different doping concentrations including a bottom epitaxial layer with a doping concentration D1 and a top epitaxial layer above said bottom epitaxial layer with a doping concentration D2, wherein said D2<said D1, and said buffer region having a doping concentration DB, wherein said D2<said DB<said D1.

20. The SiC SGT device of claim 17, further comprising a current spreading region of said first conductivity type surrounding at least sidewalls of said gate electrode below said body region, wherein said current spreading layer has a doping concentration higher than doping concentrations of said MSE layers in said OCB region.
